(19) United States
(12) Patent Application Publication
(10) Pub. No.: US 2025/0120194 A1
(43) Pub. Date: Apr. 10, 2025

(54) IMAGE SENSOR AND METHOD OF MANUFACTURING THE SAME

(71) Applicant: SAMSUNG ELECTRONICS CO., LTD, SUWON-SI (KR)

(72) Inventors: Junho YOON, Suwon-si (KR); Gyeonghee LEE, Suwon-si (KR); Dongwoon LEE, Suwon-si (KR); Jaehyeok LEE, Suwon-si (KR)

(21) Appl. No.: 18/901,417

(22) Filed: Sep. 30, 2024

(30) Foreign Application Priority Data
Oct. 10, 2023 (KR) 10-2023-0134304

(51) Int. Cl. H01L 27/146

(52) U.S. Cl. CPC H10F 39/026; H10F 39/182; H10F 39/8053; H10F 39/8057; H10F 39/8063; H10F 39/811

(57) ABSTRACT

An image sensor includes a substrate including a first region and a second region. A photodiode is in the first region of the substrate. A color filter array layer is on the first region of the substrate. The color filter array layer includes color filters. A pad structure extends through an upper portion of the second region of the substrate and protrudes upwardly over an upper surface of the substrate in a vertical direction substantially perpendicular to the upper surface of the substrate. A dummy structure is spaced apart from the pad structure on the second region of the substrate.

### CROSS-REFERENCE TO RELATED APPLICATION

This application claims priority under 35 U.S.C. § 119 to Korean Patent Application No. 10-2023-0134304, filed on Oct. 10, 2023 in the Korean Intellectual Property Office, the disclosure of which is incorporated by reference in its entirety herein.

### TECHNICAL FIELD

Embodiments of the present disclosure relate to an image sensor.

### DISCUSSION OF RELATED ART

The manufacture of an image sensor may include the forming of a color filter layer. An exposure process and a developing process may be performed on the color filter layer to form a plurality of color filters. However, if the color filter layer is not formed uniformly in an active pixel region in which active pixels are formed, spots may be formed resulting in a decrease in image quality.

### SUMMARY

Example embodiments provide an image sensor having increased characteristics.

Example embodiments provide a method of manufacturing an image sensor having increased characteristics.

According to an embodiment of the present disclosure, an image sensor includes a substrate including a first region and a second region. A photodiode is in the first region of the substrate. A color filter array layer is on the first region of the substrate. The color filter array layer includes color filters. A pad structure extends through an upper portion of the second region of the substrate and protrudes upwardly over an upper surface of the substrate in a vertical direction substantially perpendicular to the upper surface of the substrate. A dummy structure is spaced apart from the pad structure on the second region of the substrate. A microlens is on the color filter array layer.

According to an embodiment of the present disclosure, an image sensor includes a substrate including a first region and a second region. A photodiode is in the first region of the substrate. A color filter array layer is on the first region of the substrate. The color filter array layer includes color filters. A pad structure extends through an upper portion of the second region of the substrate and protrudes upwardly over an upper surface of the substrate in a vertical direction substantially perpendicular to the upper surface of the substrate. The pad structure includes a pad layer. A conductive pattern is on a sidewall and a lower surface of the pad layer. A barrier pattern is on a sidewall and a lower surface of the conductive pattern. A dummy structure is spaced apart from the pad structure on the second region of the substrate. The dummy structure includes a first dummy pattern and a second dummy pattern stacked in the vertical direction. A microlens is on the color filter array layer. The first dummy pattern and the second dummy pattern include substantially same materials as the barrier pattern and the conductive pattern, respectively.

According to an embodiment of the present disclosure, an image sensor includes a first substrate including a first region, a second region surrounding the first region, and a third region surrounding the second region in an inside of the first substrate and a space over and under the first substrate. A first insulating interlayer is on the first substrate. The first insulating interlayer contains first wirings in the third region. A second insulating interlayer is on the first insulating interlayer. The second insulating interlayer contains second wirings in the third region. A second substrate is on the second insulating interlayer. A separation pattern is in the second substrate in the first and second regions. The separation pattern defines unit pixel regions. Unit pixels are disposed in the unit pixel regions. A photodiode is in each of the unit pixel regions of the second substrate. A transfer gate (TG) extends through a lower portion of the second substrate and contacts the photodiode. A floating diffusion (FD) region is at a lower portion of the second substrate adjacent to the TG. A planarization layer is on the second substrate. A color filter array layer is on the planarization layer in the first region. The color filter array layer includes color filters. An interference blocking structure is between the color filters. A microlens is on the color filter array layer. A light blocking structure is on the planarization layer. A through via structure extends through the planarization layer, the second substrate, the second insulating interlayer and an upper portion of the first insulating interlayer in the third region. The through via structure contacts the first and second wirings. A pad structure extends through the planarization layer and an upper portion of the second substrate in the third region and protrudes upwardly over an upper surface of the substrate in a vertical direction substantially perpendicular to the upper surface of the substrate. A dummy structure is spaced apart from the pad structure on the planarization layer in the third region.

In the image sensor in accordance with embodiments of the present disclosure, spots may not be formed in the active pixel region, and thus the image sensor may have increased electrical characteristics.

### BRIEF DESCRIPTION OF THE DRAWINGS

FIG. 1 is a plan view illustrating first to third regions of an image sensor according to an embodiment of the present disclosure.

FIG. 2 is a cross-sectional view taken along line A-A′ of region X of FIG. 1 according to an embodiment of the present disclosure.

FIG. 3 is a plan view illustrating layouts of a pad structure and a dummy structure in region Y of FIG. 1 according to an embodiment of the present disclosure.

FIG. 4 is a cross-sectional view taken along line B-B′ of FIG. 3 according to an embodiment of the present disclosure.

FIGS. 5-10, 13 and 16 are cross-sectional views taken along line A-A′ of region X of FIG. 1 illustrating a method of manufacturing an image sensor according to embodiments of the present disclosure.

FIGS. 11 and 14 are plan views of region Y of FIG. 1 illustrating a method of manufacturing an image sensor according to embodiments of the present disclosure.

FIGS. 12 and 15 are cross-sectional views taken along lines B-B′ of FIGS. 11 and 14, respectively illustrating a method of manufacturing an image sensor according to embodiments of the present disclosure.

FIG. 17 is a plan view illustrating layouts of the pad structure and the dummy structure according to an embodiment of the present disclosure.

FIGS. 18 and 19 are cross-sectional views illustrating image sensors according to embodiments of the present disclosure.

### DETAILED DESCRIPTION OF EMBODIMENTS

Image sensors and methods of manufacturing the same in accordance with non-limiting embodiments will be more clearly understood from the following detailed description taken in conjunction with the accompanying drawings.

It will be understood that, although the terms “first,” “second,” and/or “third” may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second or third element, component, region, layer or section without departing from the teachings of inventive concepts.

First to third regions I, II and III of a reference substrate, e.g., a first substrate and/or a second substrate may refer to only an inside of the reference substrate. Alternatively, the first to third regions I, II and III may also refer to spaces over and/or under the reference substrate.

A direction substantially parallel to a surface of the reference substrate may be referred to as a horizontal direction, and a direction substantially perpendicular to the surface of the reference substrate may be referred to as a vertical direction. Two directions among the horizontal directions intersecting each other may be referred to as first and second directions D1 and D2, and the vertical direction may be referred to as a third direction D3. Each of the first to third directions D1, D2 and D3 may include not only a direction shown in the drawings but also an inverse direction thereto. In some embodiments, the first and second directions D1 and D2 may be substantially perpendicular to each other.

In the specifications, up vs. down, on and over vs. beneath and under, upper surface vs. lower surface, and upper portion vs. lower portion are relative conceptions so as to describe opposite sides in the vertical direction, and each wording may have opposite meanings according to the specific parts to be explained in the specifications.

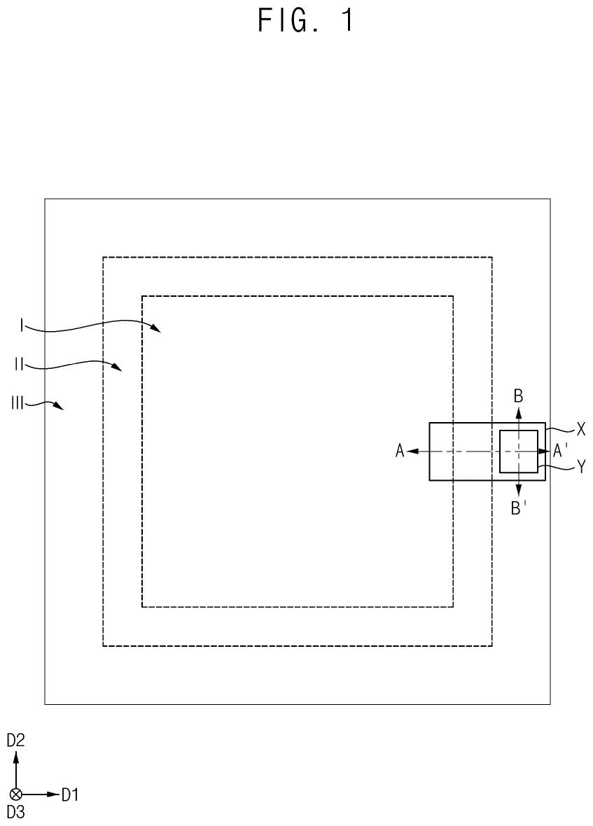

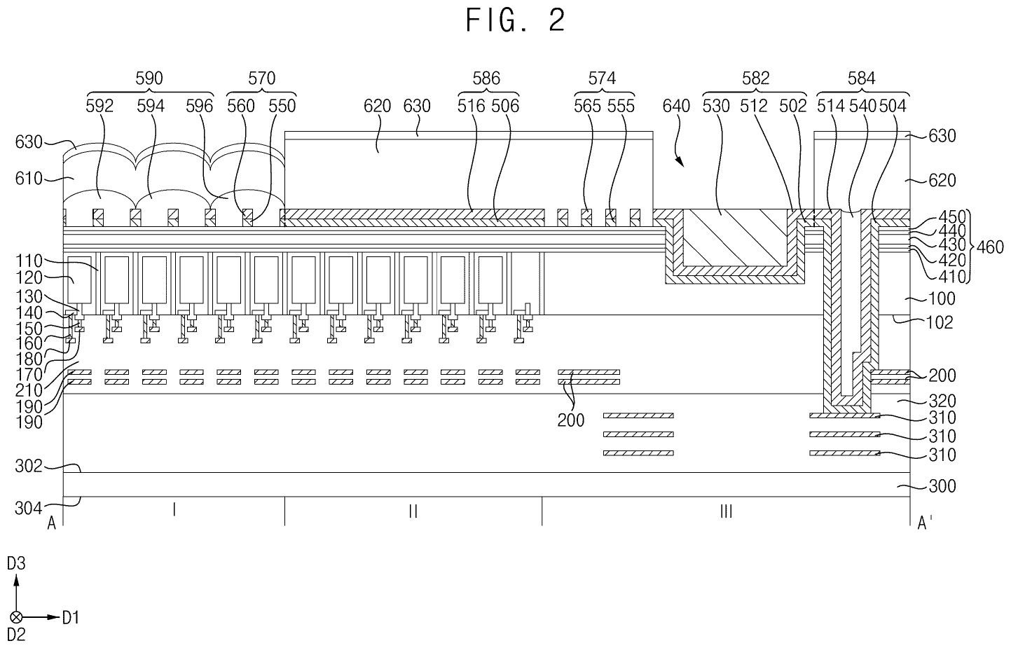

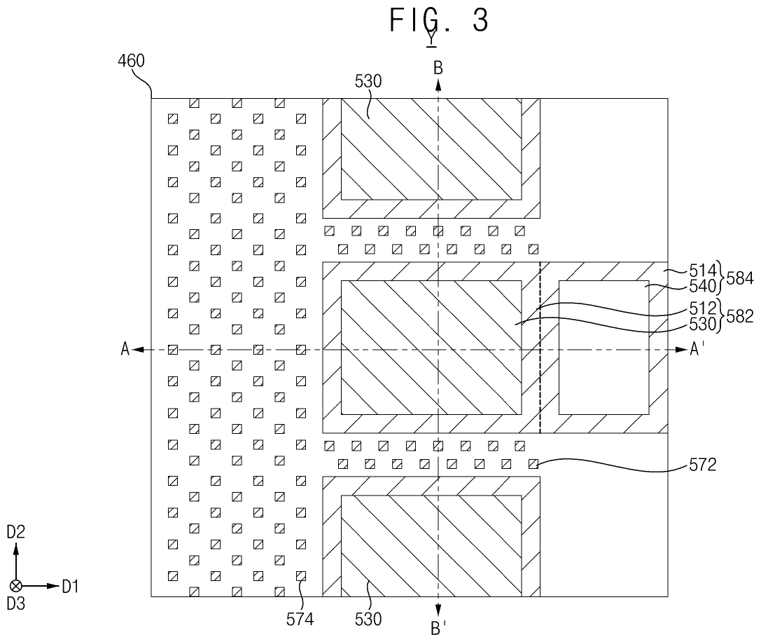

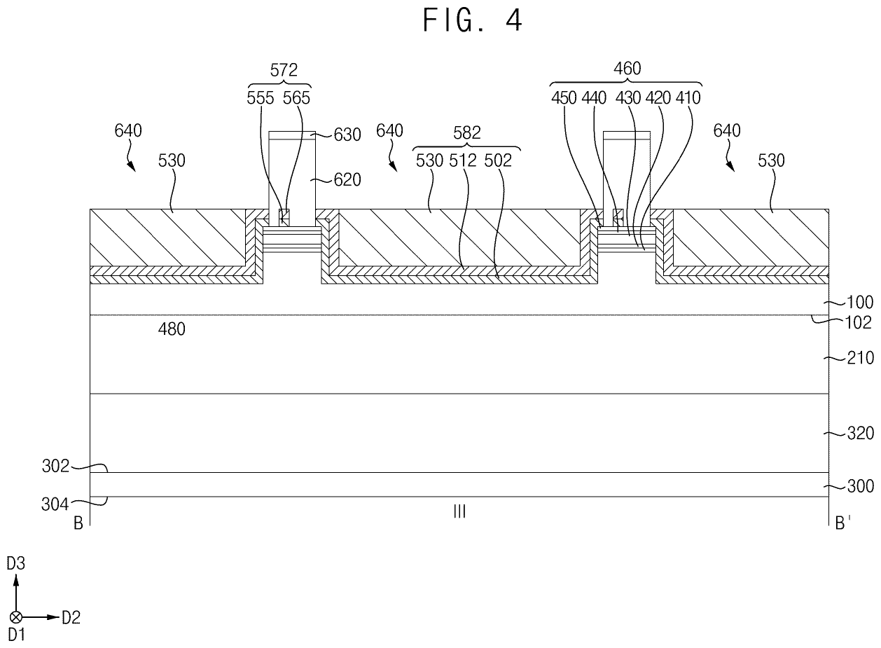

FIG. 1 is a plan view illustrating first to third regions of an image sensor in accordance with an embodiment, FIG. 2 is a cross-sectional view taken along line A-A′ of region X of FIG. 1, FIG. 3 is a plan view illustrating layouts of a pad structure and a dummy structure in region Y of FIG. 1, and FIG. 4 is a cross-sectional view taken along line B-B′ of FIG. 3.

Referring to FIGS. 1 to 4, in an embodiment the image sensor may include a second substrate 300, a second insulating interlayer 320, a first insulating interlayer 210, a first substrate 100 and a lower planarization layer 460 sequentially stacked in the third direction D3 in first to third regions I, II and III.

In an embodiment, a color filter array layer 590, a microlens 610 and a transparent electrode 630 may be sequentially stacked on the lower planarization layer 460 in the third direction D3 in the first region I, and a light blocking structure 586, an upper planarization layer 620 and the transparent electrode 630 may be sequentially stacked on the lower planarization layer 460 in the third direction D3 in the second region II.

In an embodiment, the image sensor may further include first to third wirings 170, 180 and 190 and first and second vias 150 and 160 contained in the first insulating interlayer 210, a separation pattern 110 extending in the third direction D3 through the first substrate 100, a photodiode 120 in each unit pixel region defined by the separation pattern 110, a transfer gate (TG) 130 extending through a lower portion of the first substrate 100 and having a lower portion that may protrude downwardly below a first surface 102 of the first substrate 100 and may be covered by the first insulating interlayer 210, and a floating diffusion (FD) region 140 at a lower portion of the first substrate 100 adjacent to the TG 130 in the first and second regions I and II.

In an embodiment, the image sensor may further include an interference blocking structure 570 between adjacent first to third color filters 592, 594 and 596 included in the color filter array layer 590 in the first region I.

In an embodiment, the image sensor may further include a fourth wiring 200 contained in the first insulating interlayer 210, a fifth wiring 310 contained in the second insulating interlayer 320, and a through via structure 584 extending through the lower planarization layer 460, the first substrate 100, the first insulating interlayer 210 and an upper portion of the second insulating interlayer 320 and directly contacting the fourth and fifth wirings 200 and 310 in the third region III.

In an embodiment, the image sensor may further include a pad structure 582 extending through the lower planarization layer 460 and an upper portion of the first substrate 100, and first and second dummy structures 572 and 574 on the lower planarization layer 460 in the third region III. For example, in an embodiment the pad structure 582 may protrude upwardly over an upper surface of the first substrate 100 in the third direction D3. The first and second dummy structures 572 and 574 are spaced apart from the pad structure 582 in the third region III.

The image sensor may further include various types of transistors under the first substrate 100 adjacent to the first surface 102 of the first substrate 100. For example, in an embodiment the transistors may include source follower transistors, reset transistors, select transistors, etc. The TG 130, the FD region 140 and the photodiode 120 may collectively form a transfer transistor. The photodiode 120 may serve as a source region of the transfer transistor, and the FD region 140 may serve as a drain region of the transfer transistor.

In an embodiment, each of the first and second substrates 100 and 300 may include silicon, germanium, silicon-germanium, or a III-V group compound semiconductor, such as GaP, GaAs, or GaSb. For example, in an embodiment, each of the first and second substrates 100 and 300 may be a silicon-on-insulator (SOI) substrate or a germanium-on-insulator (GOI) substrate.

In an embodiment, in a plan view, the first region I may have a shape of a rectangle or a square, the second region II may have a shape of a ring surrounding the first region I, and the third region III may have a shape of a ring surrounding the second region II. However, embodiments of the present disclosure are not necessarily limited thereto. The third region III may include a first portion extending in the first direction D1 and a second portion extending in the second direction D2.

In an embodiment, the first region I may be an active pixel region in which active pixels are formed, the second region II may be an optical black (OB) region in which OB pixels are formed, and the third region III may be a pad region or a stack region in which the pad structure 582 and the through via structure 584 are formed.

The first substrate 100 may include the first surface 102 and a second surface 104 (FIG. 4) opposite to the first surface 102 (e.g., in the third direction D3), and the second substrate 300 may include a third surface 302 and a fourth surface 304 opposite to the third surface 302 (e.g., in the third direction D3). In FIG. 2, the first surface 102 is disposed under the second surface 104, and the third surface 302 is disposed over the fourth surface 304.

In an embodiment, p-type impurities are doped into a portion or an entire portion of the first substrate 100, and a p-type well is formed in the first substrate 100.

The separation pattern 110 may extend in the third direction D3 in the first and second regions I and II of the first substrate 100, and may have a lattice pattern in the first and second regions I and II in a plan view. In an embodiment, a plurality of unit pixel regions that may be defined by the separation pattern 110 may be arranged in each of the first and second directions D1 and D2.

For example, the photodiode 120 may be an n-type impurity region doped with n-type impurities in the p-type well in the first and second regions I and II of the first substrate 100, and thus the photodiode 120 and the p-type well may collectively form a PN junction diode. In an embodiment, a p-type impurity region highly doped with p-type impurities at a portion of the first substrate 100 adjacent to the separation pattern 110 may be further formed, so that the PN junction diode may have increased electric characteristics.

The photodiode 120 may be disposed in each unit pixel region defined by the separation pattern 110 in the first and second regions I and II of the first substrate 100. However, in an embodiment the photodiode 120 may not be disposed in some of the unit pixel regions defined by the separation pattern 110 in the second region II of the first substrate 100.

The TG 130 may include a buried portion extending in the third direction D3 upwardly from the first surface 102 of the first substrate 100 and a protruding portion beneath the buried portion and having a lower surface that is lower than the first surface 102 of the first substrate 100 (e.g., in the third direction D3). In an embodiment, the TG 130 may directly contact the photodiode 120.

The FD region 140 may be disposed at a portion of the first substrate 100 adjacent to the first surface 102 of the first substrate 100 and the TG 130, and may be an impurity region doped with impurities, such as n-type impurities.

In an embodiment, the first via 150 may directly contact the TG 130, and may be connected to the first wiring 170. The second via 160 may directly contact the FD region 140, and may be connected to the second wiring 180.

Vias and wirings connected to transistors, such as the source follower transistors, the reset transistors and the select transistors may be further formed in the first insulating interlayer 210 in the first and second regions I and II. FIG. 2 shows that the third wirings 190 are disposed at two levels in the third direction D3 and the fourth wirings 200 are disposed at two levels in the third direction D3. However, embodiments of the present disclosure are not necessarily limited thereto and the number of levels in the third direction D3 that the third wirings 190 and the fourth wirings 200 may respectively be disposed may vary.

In an embodiment, each of the first and second insulating interlayers 210 and 320 may include an oxide, such as silicon oxide, or a low-k dielectric material.

In an embodiment, the lower planarization layer 460 may include first to fifth layers 410, 420, 430, 440 and 450 sequentially stacked in the third direction D3. For example, in an embodiment the first to fifth layers 410, 420, 430, 440 and 450 may include aluminum oxide, hafnium oxide, silicon oxide, silicon nitride and hafnium oxide, respectively.

The interference blocking structure 570 may be disposed on the lower planarization layer 460 (e.g., disposed directly thereon in the third direction D3), and may overlap the separation pattern 110 in the third direction D3. For example, in an embodiment the interference blocking structure 570 may have a shape of a lattice in a plan view. In an embodiment, the interference blocking structure 570 may include a first interference blocking pattern 550 and a second interference blocking pattern 560 sequentially stacked in the third direction D3. In an embodiment, an upper surface of the interference blocking structure 570 may be disposed at a substantially same height (e.g., in the third direction D3) as upper surfaces of the first and second dummy structures 572, 574. In an embodiment, the first interference blocking pattern 550 may include a metal nitride, such as titanium nitride, and the second interference blocking pattern 560 may include a metal, such as tungsten.

In an embodiment, the color filter array layer 590 may include a plurality of color filters, such as first to third color filters 592, 594 and 596. For example, in an embodiment, the first to third color filters 592, 594 and 596 may be a green color filter (G), a blue color filter (B) and a red color filter (R). However, embodiments of the present disclosure are not necessarily limited thereto and the number of the color filters and the colors of the color filters may vary.

The light blocking structure 586 may include a third barrier pattern 506 and a third conductive pattern 516 sequentially stacked in the third direction D3 on the lower planarization layer 460. In a plan view, the light blocking structure 586 may have a shape of a ring covering the second region II. The third barrier pattern 506 may include a metal nitride, such as titanium nitride, and the third conductive pattern 516 may include a metal, such as tungsten.

A microlens 610 may be disposed on (e.g., disposed directly thereon) the color filter array layer 590 in the first region I. The upper planarization layer 620 may be disposed on (e.g., disposed directly thereon) the light blocking structure 586, the first and second dummy structures 572 and 574 and the through via structure 584 in the second and third regions II and III. In some embodiments, the upper planarization layer 620 may include a second opening 640 exposing an upper surface of the pad structure 582 in the third region III. In an embodiment, the microlens 610 and the upper planarization layer 620 may include substantially the same material as each other, such as a photoresist material having a high transparency.

The transparent electrode layer 630 may be disposed on the microlens 610 and the upper planarization layer 620 (e.g., disposed directly thereon in the third direction D3). In an embodiment, the transparent electrode layer 630 may include ITO, IZO, ZnO, SnO₂, antimony-doped tin oxide (ATO), antimony-doped zinc oxide (AZO), gallium-doped zinc oxide (GZO), TiO₂, fluorine-doped tin oxide (FTO), etc.

In an embodiment, the pad structure 582 may include a pad layer 530, and a first conductive pattern 512 and a first barrier pattern 502 sequentially stacked on a sidewall and a lower surface of the pad layer 530. For example, the first conductive pattern 512 may be disposed on (e.g., directly thereon) a sidewall and a lower surface of the pad layer 530. The first barrier pattern 502 may be disposed on (e.g., disposed directly thereon) a sidewall and a lower surface of the first conductive pattern 512. The through via structure 584 may include a filling layer 540, and a second conductive pattern 514 and a second barrier pattern 504 sequentially stacked on a sidewall and a lower surface of the filling layer 540.

In an embodiment, the pad layer 530 may include a metal, such as aluminum, and the filling layer 540 may include a low refractive index material (LRIM) such as porous silicon oxide, or silicon oxide such as tetraethyl orthosilicate (TEOS). In an embodiment, each of the first and second barrier patterns 502 and 504 may include a metal nitride, such as titanium nitride, and each of the first and second conductive patterns 512 and 514 may include a metal, such as tungsten.

In an embodiment, a plurality of pad structures 582 may be spaced apart from each other in the first direction D1 or in the second direction D2 in the third region III. In an embodiment, a plurality of pad structures 582 may be spaced apart from each other in the second direction D2 in the second portion of the third region III, and a plurality of pad structures 582 may be spaced apart from each other in the first direction D1 in the first portion of the third region III. FIGS. 3 and 4 show the pad structures 582 spaced apart from each other in the second direction D2 in the second portion of the third region III.

In an embodiment, each of the pad structures 582 may be electrically connected to an upper wiring or an outer wiring, and may serve as a path for input and/or output of electrical signals from/to the active pixel to/from the OB pixel.

However, in an embodiment, some of the pad structures 582 may be a dummy pad structure that is not connected to the upper wiring or the outer wiring. In an embodiment, the dummy pad structure may not include the pad layer 530, and in this case, the dummy pad structure may further include a layer containing substantially the same material as the filling layer 540.

A single through via structure 584 or a plurality of through via structures 584 may be disposed in the third region III, and may directly contact the pad structure 582 or indirectly contact the pad structure through another wiring. FIGS. 2 and 3 show that the second conductive pattern 514 and the second barrier pattern 504 of the through via structure 584 directly contact the first conductive pattern 512 and the first barrier pattern 502, respectively, of the pad structure 582. However, embodiments of the present disclosure are not necessarily limited thereto.

FIG. 2 shows that the through via structure 584 is disposed at an outer region (e.g., in the first direction D1) as compared to the pad structure 582 in the third region III. However, embodiments of the present inventive concept are not necessarily limited thereto, and in some embodiments, the pad structure 582 may be disposed at an outer region as compared to the through via structure 584 in the third region III.

In an embodiment, each of the first and second dummy structures 572 and 574 may include a fifth barrier pattern 555 and a fifth conductive pattern 565 sequentially stacked on the lower planarization layer 460 in the third direction D3. In an embodiment, the fifth barrier pattern 555 may include a metal nitride, such as titanium nitride, and the fifth conductive pattern 565 may include a metal, such as tungsten. In an embodiment, a portion of the first barrier pattern 502 and a portion of the first conductive pattern 512, such as upper surfaces thereof, may be disposed at substantially same heights (e.g., in the third direction D3) as upper surfaces of the fifth barrier pattern 555 and the fifth conductive pattern 565, respectively. In an embodiment, the upper surfaces of the first interference blocking pattern 550 and the second interference blocking pattern 560 may be disposed at substantially same heights (e.g., in the third direction D3) as upper surfaces of the fifth barrier pattern 555 and the fifth conductive pattern 565, respectively.

In an embodiment, the first dummy structure 572 may be disposed between adjacent pad structures 582, and the second dummy structure 574 may be disposed at a portion of the third region III closer to the second region II than the pad structure 582. For example, in an embodiment the first dummy structure 572 may be disposed between adjacent pad structures 582 spaced apart from each other in the second direction D2 at the second portion of the third region III, or may be disposed between adjacent pad structures 582 spaced apart from each other in the first direction D1 at the first portion of the third region III.

In an embodiment, a plurality of first dummy structures 572 may be spaced apart from each other in the first direction D1 between adjacent pad structures 582 disposed in the second direction D2 to form a first dummy structure row at the second portion of the third region III, and a plurality of first dummy structure rows may be arranged in the second direction D2. In an embodiment, the first dummy structures 572 included in the first dummy structure rows, respectively, may not be aligned with each other in the second direction D2. Thus, the first dummy structures 572 at the second portion of the third region III may be arranged in a zigzag pattern along the first direction D1.

Likewise, a plurality of first dummy structures 572 may be spaced apart from each other in the second direction D2 between the adjacent pad structures 582 disposed in the first direction D1 to form a first dummy structure column at the first portion of the third region III, and a plurality of first dummy structure columns may be arranged in the first direction D1. In an embodiment, the first dummy structures 572 included in the first dummy structure columns, respectively, may not be aligned with each other in the first direction D1. Thus, the first dummy structures 572 at the first portion of the third region III may be arranged in a zigzag pattern along the second direction D2.

In an embodiment, a plurality of second dummy structures 574 may be spaced apart from each other in each of the first and second directions D1 and D2 at a portion of the third region III adjacent to the second region II to form a second dummy structure array. In an embodiment, the second dummy structures 574 included in the second dummy structure array may be aligned with each other in a fourth direction having an acute angle with respect to the first and second directions D1 and D2, and thus the second dummy structures 574 may be arranged in zigzag pattern along the first direction D1 or the second direction D2.

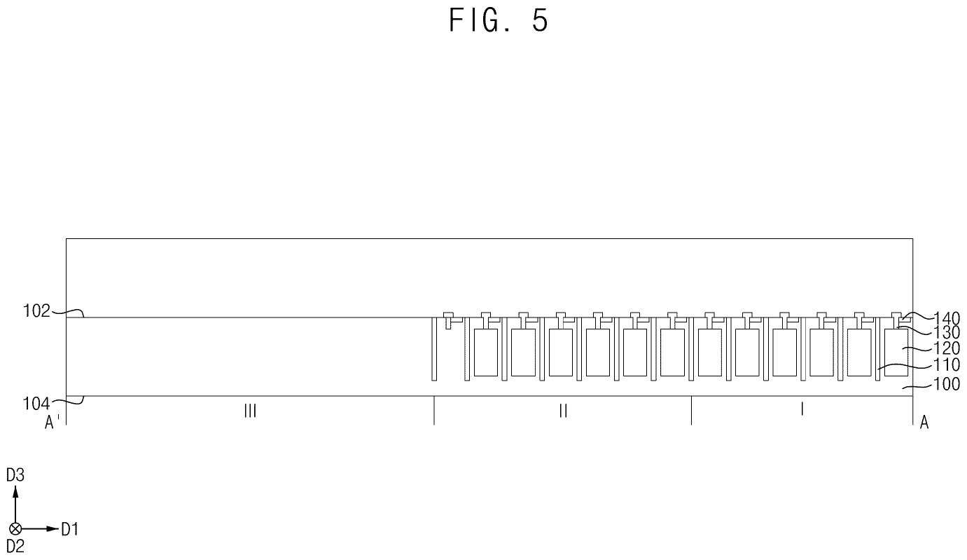

In an embodiment, a height of an upper surface of the first and second dummy structures 572, 574 may be substantially the same as a height of the upper surface of the pad structure 582 (e.g., in the third direction D3). As illustrated below with respect to FIGS. 5 to 16, as the image sensor includes the first and second dummy structures 572 and 574, when a spin coating process for forming the color filter array layer 590 included in the image sensor is performed, a space between the pad structures 582 in the third region III may not serve as a path for a movement of the color filter array layer 590. Thus, a height of an upper surface of the color filter array layer 590 may be uniform, so that the generation of spots due to the height difference of the upper surface of the color filter array layer 590 may be prevented. Accordingly, the image sensor may have increased electrical characteristics.

FIGS. 5 to 16 are cross-sectional views and plan views illustrating a method of manufacturing an image sensor in accordance with embodiments of the present disclosure.

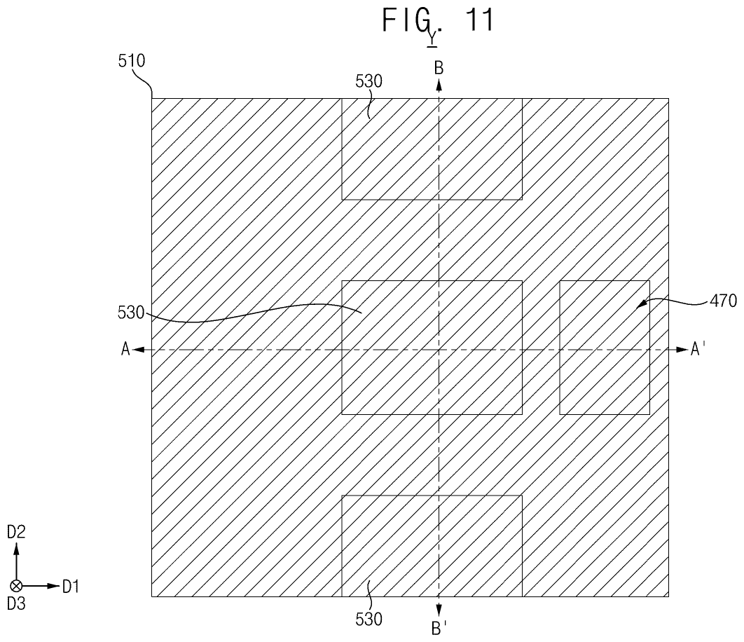

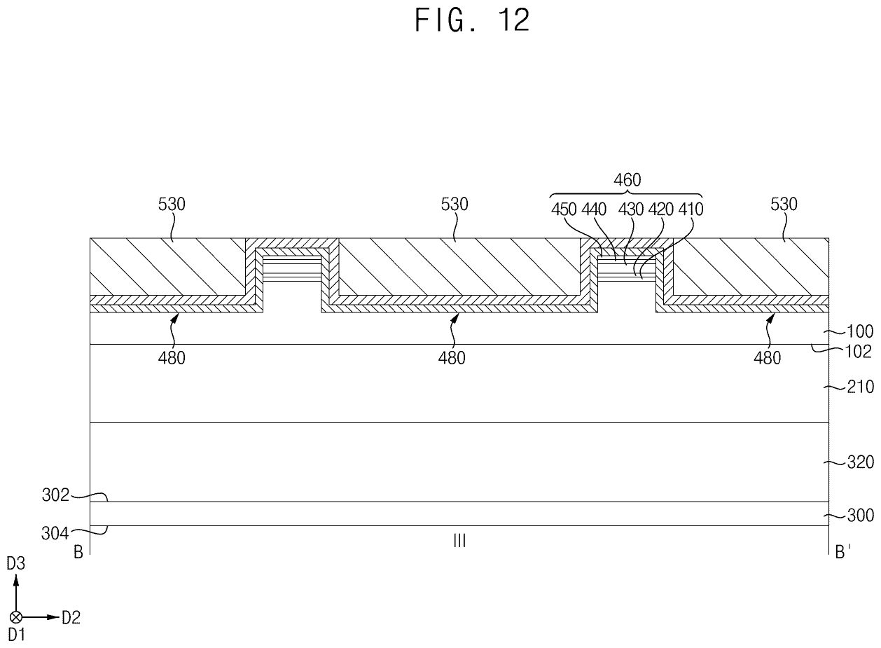

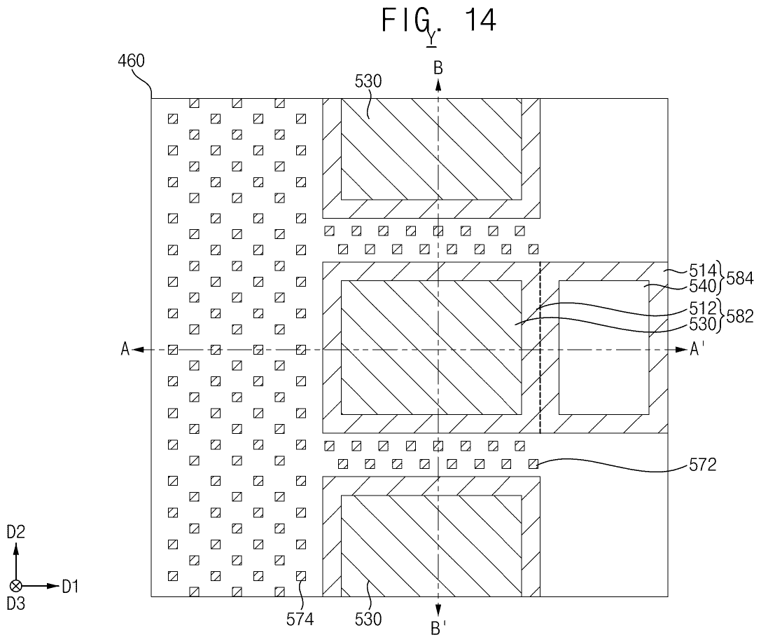

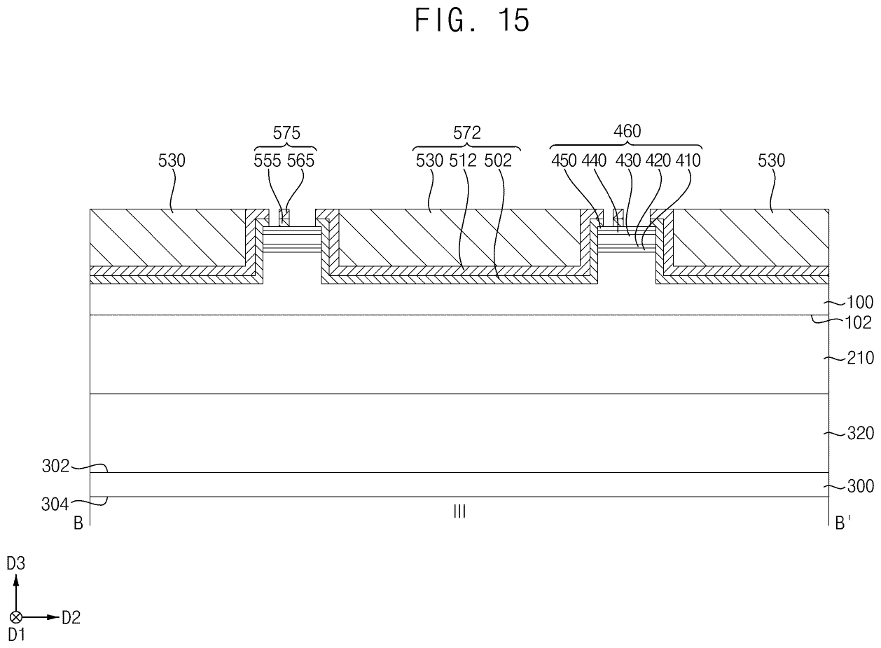

Particularly, FIGS. 5-10, 13 and 16 are cross-sectional views taken along line A-A′ of region X of FIG. 1, FIGS. 11 and 14 are plan views of region Y of FIG. 1, and FIGS. 12 and 15 are cross-sectional views taken along lines B-B′ of FIGS. 11 and 14, respectively.

Referring to FIG. 5, in an embodiment a separation pattern 110 and a photodiode 120 may be formed in the first substrate 100 including first to third regions I, II and III, and a transfer gate (TG) 130 and a floating diffusion (FD) region 140 may be formed.

In an embodiment, p-type impurities may be doped into at least a portion of the first substrate 100 to form a p-type well therein.

In an embodiment, the separation pattern 110 may be formed by forming a first trench extending in the third direction D3 downwardly from a first surface 102 of the first substrate 100 through an inside of the first substrate 100 in the first and second regions I and II. In an embodiment, the trench may not extend to the second surface 104 of the first substrate 100 but may be disposed closer to the second surface 104 of the first substrate 100 than the first surface 102 of the first substrate 100.

In an embodiment, the photodiode 120 may be a photodiode (PD). Thus, the photodiode 120 may be formed by doping n-type impurities into an inside of the p-type well in the first and second regions I and II. In an embodiment, after forming the first trench for forming the separation pattern 110, p-type impurities may be highly doped into a portion of the first substrate 100 adjacent to the first trench.

In an embodiment, the photodiode 120 may be formed after forming the separation pattern 110. However, embodiments of the present disclosure are not necessarily limited thereto, and in some embodiments the separation pattern 110 may be formed after forming the photodiode 120.

In an embodiment, the TG 130 may be formed by forming a second trench extending in the third direction D3 downwardly from the first surface 102 of the first substrate 100 through the inside of the first substrate 100. In an embodiment, the second trench may terminate at the photodiode 120.

N-type impurities may be doped into a portion of the first substrate 100 adjacent to the first surface 102 and the TG 130 to form a FD region 140. For example, in an embodiment the FD region 140 may be formed inside the first substrate 100 and a height of an upper surface of the FD region 140 may be substantially the same as a height of the first surface 102 of the first substrate 100.

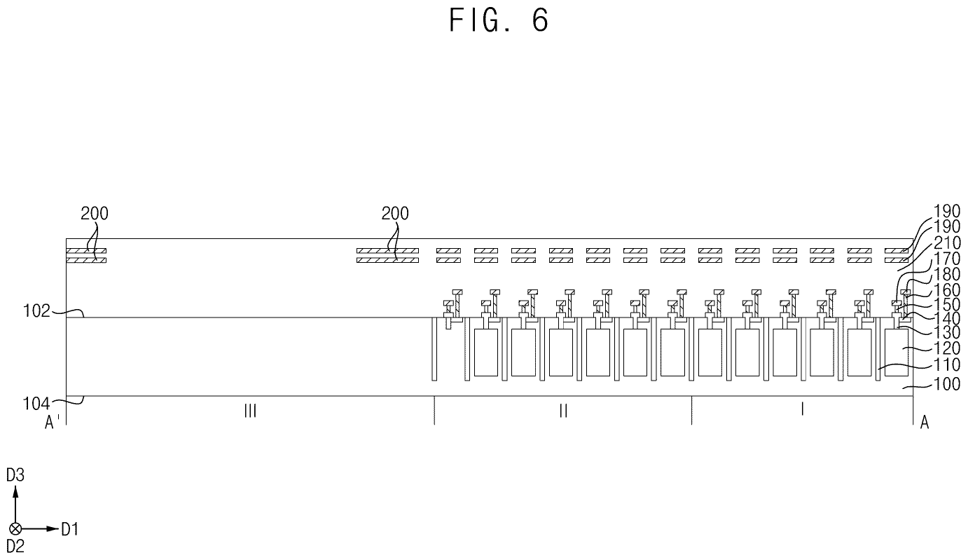

Referring to FIG. 6, in an embodiment a first insulating interlayer 210 containing first and second vias 150 and 160 and first to fourth wirings 170, 180, 190 and 200 may be formed on the first surface 102 of the first substrate 100 (e.g., formed directly thereon in the third direction D3).

In an embodiment, the first and second vias 150 and 160 and the first to fourth wirings 170, 180, 190 and 200 may be formed by a dual damascene process or a single damascene process.

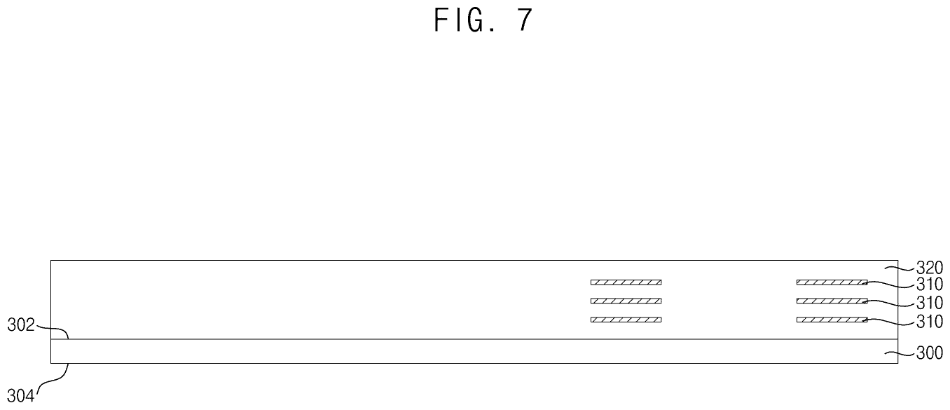

Referring to FIG. 7, in an embodiment a second insulating interlayer 320 containing a fifth wiring 310 may be formed on (e.g., formed directly thereon in the third direction D3) a third surface 302 of a second substrate 300 including the third surface 302 and a fourth surface 304 opposite to each other in the third direction D3.

FIG. 7 shows the fifth wiring 310 is formed at three levels in the third direction D3. However, embodiments of the present disclosure are not necessarily limited thereto. In an embodiment, the fifth wirings 310 may be formed by a dual damascene process or a single damascene process.

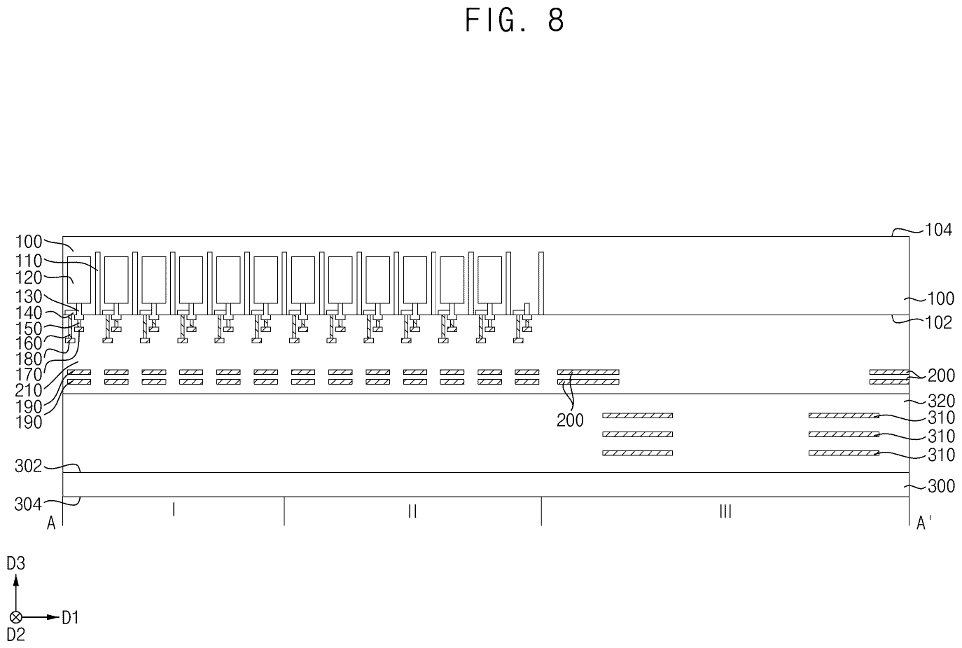

Referring to FIG. 8, the first insulating interlayer 210 on the first substrate 100 and the second insulating interlayer 320 on the second substrate 300 may be bonded to each other.

In an embodiment, the first and second insulating interlayers 210 and 320 may be bonded through a bonding layer. Alternatively, the first and second insulating interlayers 210 and 320 may be directly bonded without a bonding layer therebetween. In an embodiment, after bonding the first and second insulating interlayers 210 and 320, the bonded structure may be flipped (e.g., inverted) so that the second surface 104 of the first substrate 100 may face upward, and hereinafter, the bonded structure will be explained with an orientation having the second surface 104 of the first substrate 100 facing upward.

As the first and second substrates 100 and 300 are bonded to each other, the fifth wirings 310 on the second substrate 300 may be disposed in the third region III.

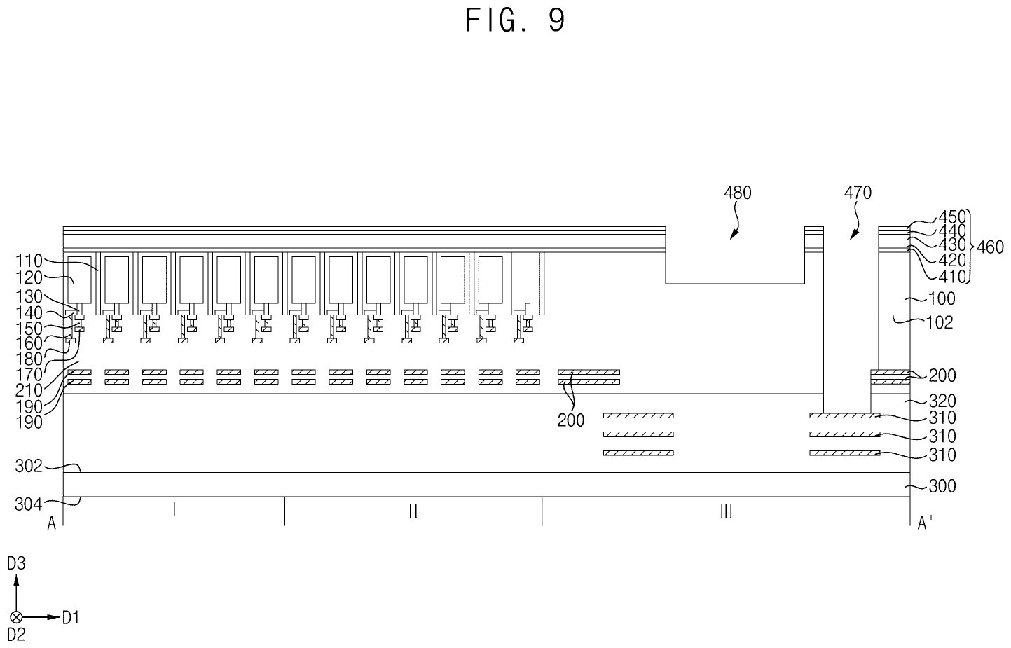

Referring to FIG. 9, a portion of the first substrate 100 adjacent to the second surface 104 thereof may be removed.

In an embodiment, the portion of the first substrate 100 adjacent to the second surface 104 thereof may be removed by a grinding process, etc. Thus, the separation pattern 110 may be exposed, and as a result, the separation pattern 110 may extend through (e.g., extend entirely therethrough in the third direction D3) the first substrate 100.

A lower planarization layer 460 may be formed on the second surface 104 of the first substrate 100 (e.g., formed directly thereon in the third direction D3).

In an embodiment, the lower planarization layer 460 may include first to fifth layers 410, 420, 430, 440 and 450 sequentially stacked in the third direction D3. In an embodiment, the first layer 410 may directly contact the exposed upper surface of the separation pattern 110.

In an embodiment, the lower planarization layer 460, the first substrate 100, the first insulating interlayer 210 and an upper portion of the second insulating interlayer 320 in the third region III may be partially removed to form a first opening 470, and the lower planarization layer 460 and an upper portion of the first substrate 100 may be partially removed to form a third trench 480.

In an embodiment, a plurality of third trenches 480 may be formed to be spaced apart from each other in the horizontal direction (e.g., the second direction D2) in the third region III.

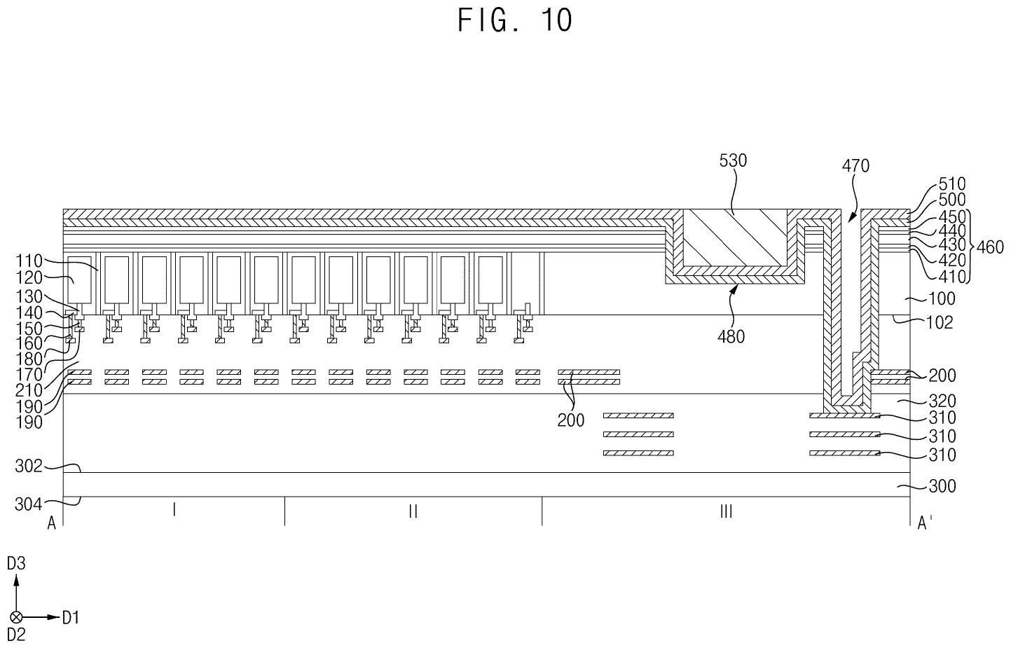

Referring to FIGS. 10 to 12, a barrier layer 500 and a conductive layer 510 may be sequentially formed on bottoms and sidewalls of the first opening 470 and the third trench 480 and an upper surface of the lower planarization layer 460, a pad layer 530 may be formed on the conductive layer 510 to fill a portion of the first opening 470 and the third trench 480, and a portion of the pad layer 530 in the first opening 470 may be removed.

In an embodiment, a height of an upper surface of the pad layer 530 in the third trench 480 and a height of an upper surface of a portion of the conductive layer 510 on the lower planarization layer 460 may be substantially the same as each other (e.g., in the third direction D3).

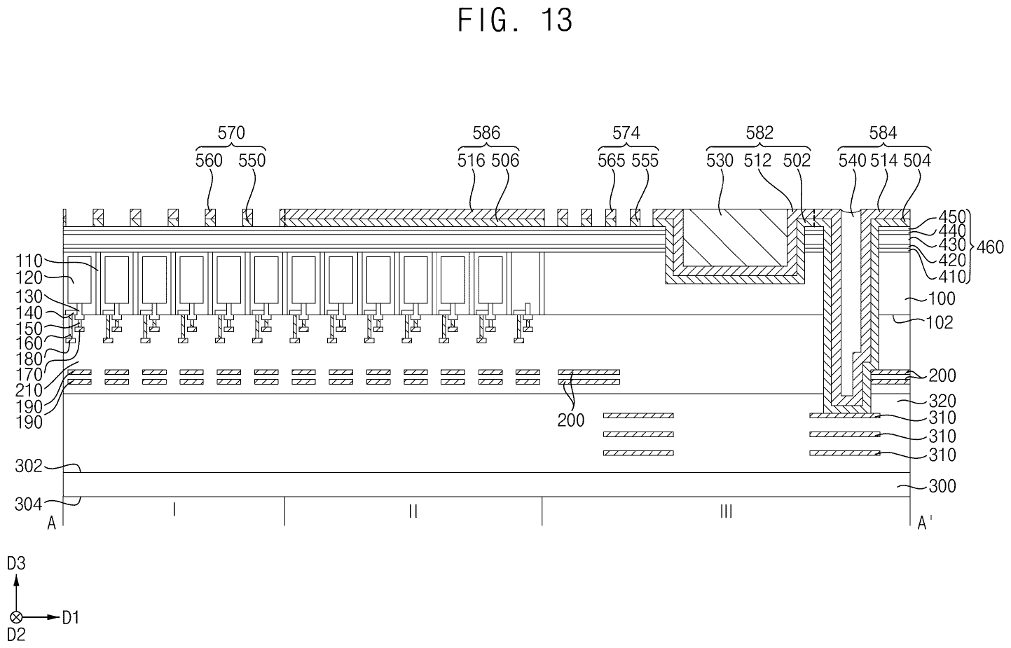

Referring to FIGS. 13 to 15, in an embodiment a filling layer 540 may be formed in the first opening 470, and the conductive layer 510 and the barrier layer 500 may be patterned to form a first conductive pattern 512 and a first barrier pattern 502 on a sidewall and a lower surface of the pad layer 530 and a second conductive pattern 514 and a second barrier pattern 504 on a sidewall and a lower surface of the filling layer 540, and a third conductive pattern 516 and a third barrier pattern 506 may remain in the second region II.

Additionally, a fourth barrier pattern 550 and a fourth conductive pattern 560 may be sequentially stacked (e.g., in the third direction D3) on the lower planarization layer 460 in the first region I, and a fifth barrier pattern 555 and a fifth conductive pattern 565 may be sequentially stacked (e.g., in the third direction D3) on the lower planarization layer 460 in the third region III.

The pad layer 530, the first conductive pattern 512 and the first barrier pattern 502 may collectively form a pad structure 582, the filling layer 540, the second conductive pattern 514 and the second barrier pattern 504 may collectively form a through via structure 584, and the third barrier pattern 506 and the third conductive pattern 516 in the second region II may collectively form a light blocking structure 586.

Additionally, the fourth barrier pattern 550 and the fourth conductive pattern 560 in the first region I may collectively form an interference blocking structure 570, and the fifth barrier pattern 555 and the fifth conductive pattern 565 in the third region III may collectively form first and second dummy structures 572 and 574. However, the fourth barrier pattern 550 and the fourth conductive pattern 560 included in the interference blocking structure 570 may also be referred to as a first interference blocking pattern 550 and a second interference blocking pattern 560, respectively, and the fifth barrier pattern 555 and the fifth conductive pattern 565 included in each of the first and second dummy structures 572 and 574 may also be referred to as a first dummy pattern 555 and a second dummy pattern 565, respectively.

In an embodiment, a plurality of pad structures 582 may be spaced apart from each other in the first direction D1 or in the second direction D2 in the third region III.

A single through via structure 584 or a plurality of through via structures 584 may be formed in the third region III. The through via structure 584 may directly contact a corresponding one of the pad structures 582 to be electrically connected thereto, or may be electrically connected to the one of the pad structures 582 through another wiring. FIGS. 13 to 15 show that the second conductive pattern 514 and the second barrier pattern 504 of the through via structure 584 directly contact the first conductive pattern 512 and the first barrier pattern 502, respectively, of the pad structure 582. However, embodiments of the present disclosure are not necessarily limited thereto.

In an embodiment, the first dummy structure 572 may be disposed between adjacent pad structures 582, and the second dummy structure 574 may be disposed at a portion of the third region III closer to the second region II than the pad structure 582. For example, the first dummy structure 572 may be disposed between adjacent pad structures 582 spaced apart from each other in the second direction D2 at the second portion of the third region III, or may be disposed between adjacent pad structures 582 spaced apart from each other in the first direction D1 at the first portion of the third region III.

In an embodiment, a plurality of first dummy structures 572 may be spaced apart from each other in the first direction D1 between adjacent pad structures 582 disposed in the second direction D2 to form a first dummy structure row at the second portion of the third region III, and a plurality of first dummy structure rows may be arranged in the second direction D2. In an embodiment, the first dummy structures 572 included in the first dummy structure rows, respectively, may not be aligned with each other in the second direction D2. Thus, the first dummy structures 572 at the second portion of the third region III may be arranged in a zigzag pattern along the first direction D1.

Likewise, a plurality of first dummy structures 572 may be spaced apart from each other in the second direction D2 between adjacent pad structures 582 disposed in the first direction D1 to form a first dummy structure column at the first portion of the third region III, and a plurality of first dummy structure columns may be arranged in the first direction D1. In an embodiment, the first dummy structures 572 included in the first dummy structure columns, respectively, may not be aligned with each other in the first direction D1. Thus, the first dummy structures 572 at the first portion of the third region III may be arranged in a zigzag pattern along the second direction D2.

In an embodiment, a plurality of second dummy structures 574 may be spaced apart from each other in each of the first and second directions D1 and D2 at a portion of the third region III adjacent to the second region II to form a second dummy structure array. In an embodiment, the second dummy structures 574 included in the second dummy structure array may be aligned with each other in a fourth direction having an acute angle with respect to the first and second directions D1 and D2, and thus the second dummy structures 574 may be arranged in zigzag pattern along the first direction D1 or the second direction D2.

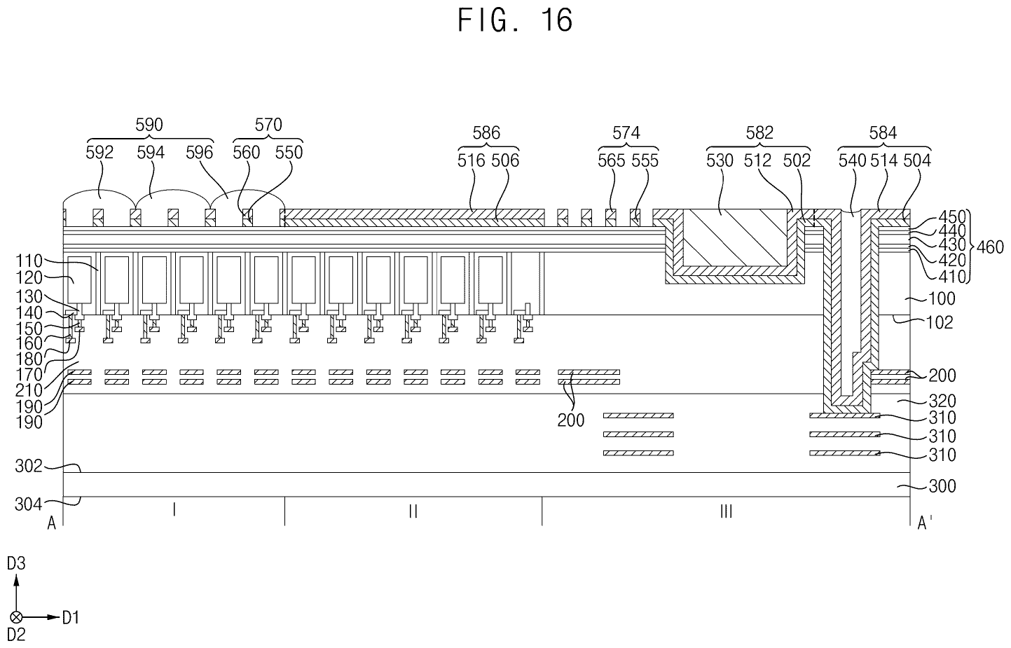

Referring to FIG. 16, a color filter layer may be formed on (e.g., formed directly thereon in the third direction D3) the lower planarization layer 460 by a spin coating process, and an exposure process and a developing process may be performed on the color filter layer to form a color filter array layer 590 including first to third color filters 592, 594 and 596 between the interference blocking structures 570 in the first region I.

In a comparative embodiment, when the spin coating process is performed, due to height difference between an upper surface of the pad structures 582 in the third region III and an upper surface of a portion of the lower planarization layer 460 on which the pad structures 582 are not formed, a space on the portion of the lower planarization layer 460 between the pad structures 582 may serve as a path for movement of the color filter layer. Thus, a height of an upper surface of the color filter layer coated in the first region I may not be uniform but may vary according to the direction of the movement, which may cause spots.

However, in an embodiment of the present disclosure, the first dummy structures 572 may be formed on the portion of the lower planarization layer 460 between the pad structures 582, and the first dummy structures 572 may not be arranged to be aligned with each other but may be arranged in a zigzag pattern. Thus, the space may not serve as the path for the movement of the color filter layer. Accordingly, the height of the upper surface of the color filter layer coated in the first region I by the spin coating process may be uniform, and thus spots may not be generated.

In an embodiment, a rinsing process using a cleaning solution including deionized water and a drying process for drying the cleaning solution may be further performed to remove a remaining portion of the color filter layer.

Referring to FIGS. 1 to 4 again, in an embodiment an upper planarization layer 620 may be formed on the color filter array layer 590, the pad structure 582, the through via structure 584, the light blocking structure 586 and the first and second dummy structures 572 and 574, and a patterning process and a reflow process may be performed on the upper planarization layer 620 to form a microlens 610.

A transparent electrode layer 630 may be formed on (e.g., formed directly thereon in the third direction D3) the microlens 610 and the upper planarization layer 620, and a portion of the transparent electrode layer 630 overlapping the pad structure 582 in the third direction D3 in the third region III and a portion of the upper planarization layer 620 thereunder may be removed to form a second opening 640 exposing an upper surface of the pad structure 582.

In an embodiment, an upper wiring may be further formed to be electrically connected to the pad structure 582 to complete the fabrication of the image sensor.

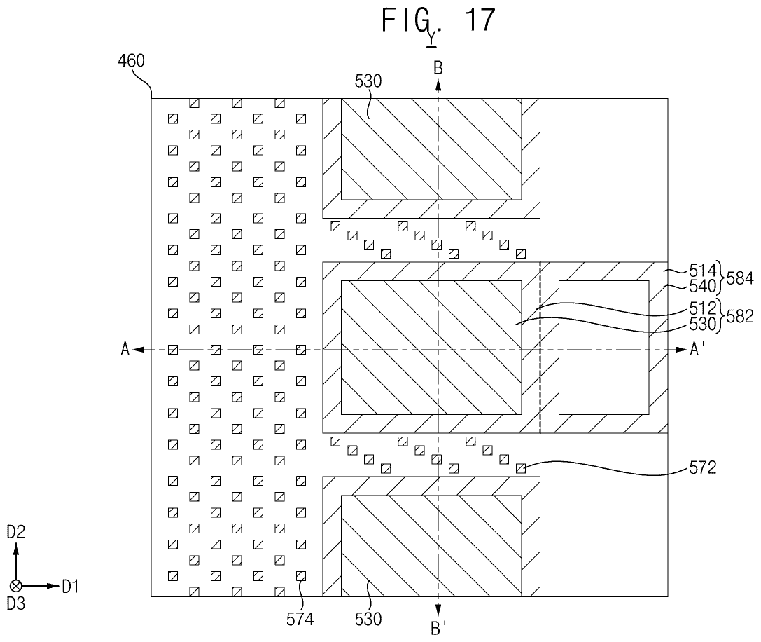

FIG. 17 is a plan view illustrating layouts of the pad structure and the dummy structure in accordance with an embodiment, which may correspond to FIG. 3.

Referring to FIG. 17, the first dummy structures 572 between the pad structures 582 adjacent to each other in the second direction D2 at the second portion of the third region III may be aligned with each other in a direction having an acute angle with respect to the first and second directions D1 and D2 to form a first dummy structure group, and a plurality of first dummy structure groups may be arranged along the first direction D1.

Thus, the space between the pad structures 582 may not serve as the path for the movement of the color filter layer due to the first dummy structures 572, so that the upper surface of the color filter layer coated in the first region I by a spin coating process may have a uniform height to prevent spots being generated.

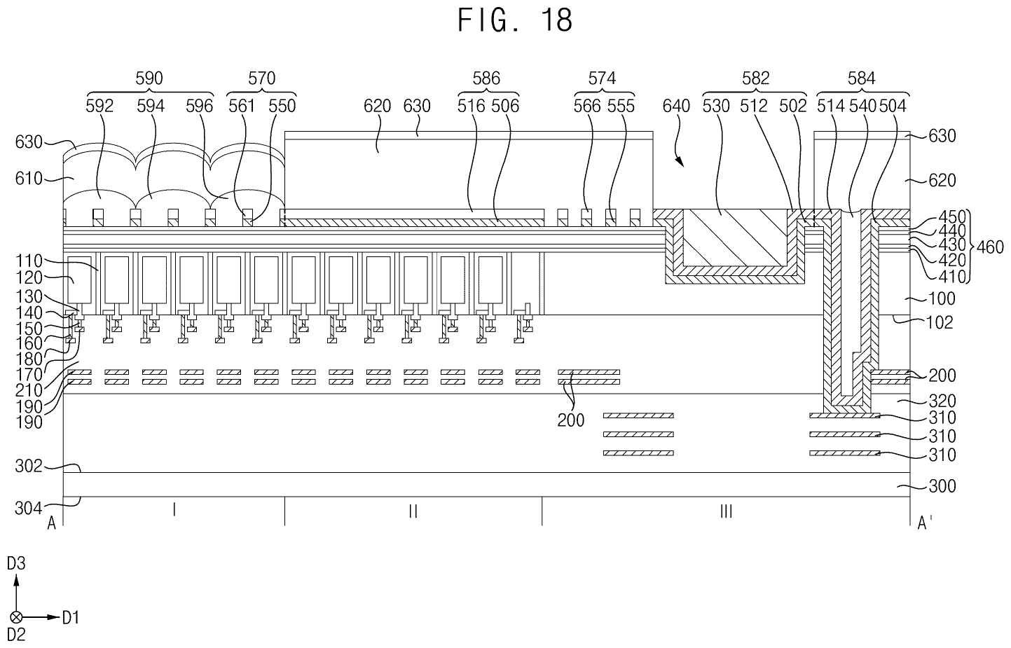

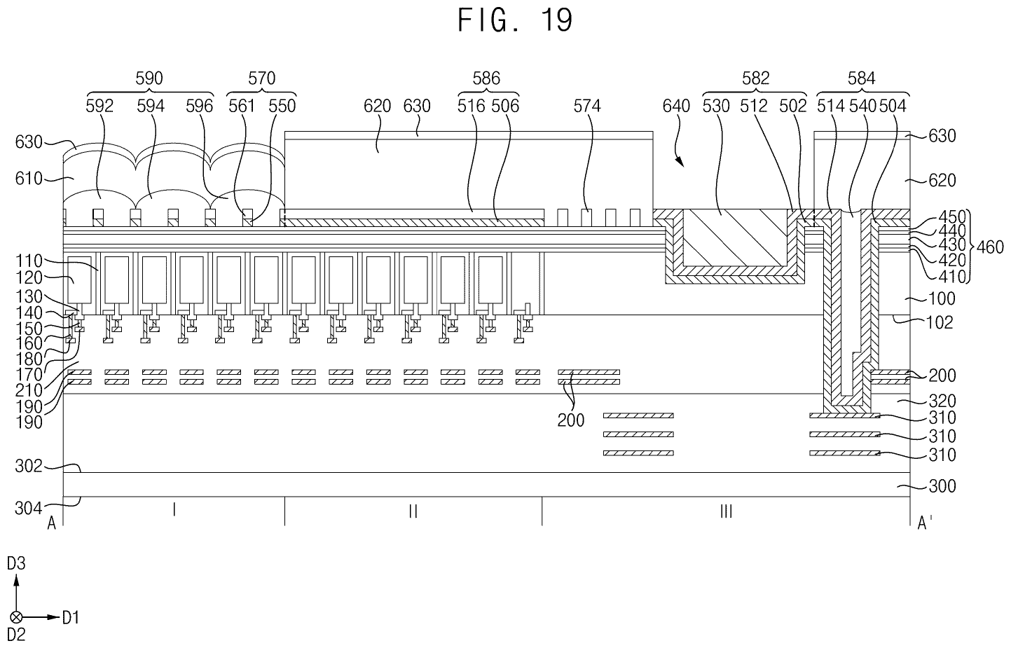

FIGS. 18 and 19 are cross-sectional views illustrating image sensors in accordance with embodiments of the present disclosure, which may correspond to FIG. 2. These image sensors may be substantially the same as or similar to that of FIGS. 1 to 4, except for the dummy structures and the interference blocking structure, and thus repeated explanations may be omitted herein for economy of explanation.

Referring to FIG. 18, in an embodiment the interference blocking structure 570 may include the first interference blocking pattern 550 and a third interference blocking pattern 561 sequentially stacked on the lower planarization layer 460 (e.g., in the third direction D3), and each of the first and second dummy structures 572 and 574 may include the first dummy pattern 555 and a third dummy pattern 566 sequentially stacked on the lower planarization layer 460 (e.g., in the third direction D3).

In an embodiment, each of the third interference pattern 561 and the third dummy pattern 566 may include an LRIM such as porous silicon oxide or silicon oxide such as TEOS.

Referring to FIG. 19, in an embodiment the interference blocking structure 570 may include the first interference blocking pattern 550 and the third interference blocking pattern 561 sequentially stacked on the lower planarization layer 460 (e.g., in the third direction D3), and each of the first and second dummy structures 572 and 574 may include a fourth dummy pattern having a single layered structure. In an embodiment, the fourth dummy pattern may include an LRIM such as porous silicon oxide or silicon oxide such as TEOS.

As described above, although the present invention has been described with reference to non-limiting embodiments, those skilled in the art will readily appreciate that many modifications are possible in the described embodiments without materially departing from the novel teachings and advantages of the present disclosure.

What is claimed is:

1. An image sensor comprising:
a substrate including a first region and a second region;
a photodiode in the first region of the substrate;
a color filter array layer on the first region of the substrate, the color filter array layer including color filters;
a pad structure extending through an upper portion of the second region of the substrate and protruding upwardly over an upper surface of the substrate in a vertical direction substantially perpendicular to the upper surface of the substrate;
a plurality of dummy structures, each of the plurality of dummy structures being spaced apart from the pad structure on the second region of the substrate; and
a microlens on the color filter array layer,
wherein each of the plurality of dummy structures are spaced apart from each other in a first direction, and
wherein the first direction is parallel to the upper surface of the substrate.

2. The image sensor of claim 1, wherein the plurality of dummy structures comprise more than 20 dummy structures.

3. The image sensor of claim 2, wherein the pad structure includes a plurality of pad structures spaced apart from each other in the first direction,
wherein the plurality of dummy structures are arranged between adjacent pad structures of the plurality of pad structures in a zigzag pattern in a second direction substantially parallel to the upper surface of the substrate and substantially perpendicular to the first direction.

4. The image sensor of claim 2, wherein the pad structure includes a plurality of pad structures spaced apart from each other in the first direction,
wherein the plurality of dummy structures are arranged between adjacent pad structures of the plurality of pad structures in a second direction substantially parallel to the upper surface of the substrate, the plurality of dummy structures are arranged in an acute angle with respect to the first direction.

5. The image sensor of claim 4, wherein the plurality of dummy structures form a dummy structure group, and
wherein the image sensor includes a plurality of dummy structure groups spaced apart from each other in a third direction different from the first direction.

6. The image sensor of claim 5, wherein the dummy structure includes:
a first dummy structure between the adjacent pad structures of the plurality of pad structures; and
a second dummy structure on a portion of the second region of the substrate closer to the first region of the substrate than the plurality of pad structures.

7. The image sensor of claim 6, wherein the dummy structure includes a plurality of second dummy structures spaced apart from each other in the first direction and the third direction.

8. The image sensor of claim 1, wherein the dummy structure includes a first dummy pattern and a second dummy pattern sequentially stacked in the vertical direction.

9. The image sensor of claim 8, wherein:
the first dummy pattern includes a metal nitride; and
the second dummy pattern includes a metal.

10. The image sensor of claim 8, wherein:
the first dummy pattern includes a metal nitride; and
the second dummy pattern includes a low refractive index material.

11. The image sensor of claim 10, wherein the pad structure includes:
a pad layer;
a conductive pattern on a sidewall and a lower surface of the pad layer; and
a barrier pattern on a sidewall and a lower surface of the conductive pattern, and
wherein a portion of the barrier pattern and a portion of the conductive pattern are disposed at substantially same heights as the first dummy pattern and the second dummy pattern, respectively, on the substrate.

12. The image sensor of claim 11, wherein the barrier pattern and the conductive pattern include a substantially same material as the first dummy pattern and the second dummy pattern, respectively.

13. The image sensor of claim 1, wherein the dummy structure includes a low refractive index material or silicon oxide.

14. The image sensor of claim 1, further comprising an interference blocking structure between the color filters on the substrate.

15. An image sensor comprising:
a substrate including a first region and a second region;
a photodiode in the first region of the substrate;
a color filter array layer on the first region of the substrate, the color filter array layer including color filters;
a pad structure extending through an upper portion of the second region of the substrate and protruding upwardly over an upper surface of the substrate in a vertical direction substantially perpendicular to the upper surface of the substrate, the pad structure including:
a pad layer;
a conductive pattern on a sidewall and a lower surface of the pad layer; and
a barrier pattern on a sidewall and a lower surface of the conductive pattern,
a dummy structure spaced apart from the pad structure on the second region of the substrate, the dummy structure including a first dummy pattern and a second dummy pattern stacked in the vertical direction; and
a microlens on the color filter array layer,
wherein the first dummy pattern and the second dummy pattern include substantially same materials as the barrier pattern and the conductive pattern, respectively.

16. The image sensor of claim 15, wherein a height of the first dummy pattern from the upper portion of the second region of the substrate is substantially the same as a height of the second dummy pattern from the upper portion of the second region of the substrate.

17. The image sensor of claim 15, further comprising an interference blocking structure between the color filters on the substrate,
wherein the interference blocking structure includes a first interference blocking pattern and a second interference blocking pattern stacked in the vertical direction, and
wherein the first interference blocking pattern and the second interference blocking include substantially same materials as the barrier pattern and the conductive pattern, respectively.

18. An image sensor comprising:
a first substrate including a first region, a second region surrounding the first region, and a third region surrounding the second region in an inside of the first substrate and a space over and under the first substrate;
a first insulating interlayer on the first substrate, the first insulating interlayer containing first wirings in the third region;
a second insulating interlayer on the first insulating interlayer, the second insulating interlayer containing second wirings in the third region;
a second substrate on the second insulating interlayer;
a separation pattern in the second substrate in the first and second regions, the separation pattern defining unit pixel regions, wherein unit pixels are disposed in the unit pixel regions;
a photodiode in each of the unit pixel regions of the second substrate;
a transfer gate (TG) extending through a lower portion of the second substrate and contacting the photodiode;
a floating diffusion (FD) region at a lower portion of the second substrate adjacent to the TG;
a planarization layer on the second substrate;
a color filter array layer on the planarization layer in the first region, the color filter array layer including color filters;
an interference blocking structure between the color filters;
a microlens on the color filter array layer;
a light blocking structure on the planarization layer;
a through via structure extending through the planarization layer, the second substrate, the second insulating interlayer and an upper portion of the first insulating interlayer in the third region, the through via structure contacting the first and second wirings;
a pad structure extending through the planarization layer and an upper portion of the second substrate in the third region and protruding upwardly over an upper surface of the substrate in a vertical direction substantially perpendicular to the upper surface of the substrate; and
a dummy structure spaced apart from the pad structure on the planarization layer in the third region.

19. The image sensor of claim 18, wherein:
the pad structure includes a plurality of pad structures spaced apart from each other in a first direction substantially parallel to the upper surface of the substrate;
the dummy structure includes a plurality of dummy structures,
wherein the plurality of dummy structures are arranged between adjacent pad structures of the plurality of pad structures in a zigzag pattern in a second direction substantially parallel to the upper surface of the substrate and substantially perpendicular to the first direction.

20. The image sensor of claim 18, wherein:
the pad structure includes a plurality of pad structures spaced apart from each other in a first direction substantially parallel to the upper surface of the substrate;
the dummy structure includes a plurality of dummy structures,
wherein the plurality of dummy structures are arranged between adjacent pad structures of the plurality of pad structures in a second direction substantially parallel to the upper surface of the substrate and having an acute angle with respect to the first direction.
